(19) United States
(12) Patent Application Publication
(10) Pub. No.: US 2019/0273169 A1
(43) Pub. Date: Sep. 5, 2019

(54) ELECTRONIC DEVICE INCLUDING A JUNCTION FIELD-EFFECT TRANSISTOR HAVING A GATE WITHIN A WELL REGION AND A PROCESS OF FORMING THE SAME

(71) Applicant: SEMICONDUCTOR COMPONENTS INDUSTRIES, LLC, Phoenix, AZ (US)

(72) Inventor: Moshe AGAM, Portland, OR (US)

(73) Assignee: SEMICONDUCTOR COMPONENTS INDUSTRIES, LLC, Phoenix, AZ (US)

(21) Appl. No.: 15/909,622

(22) Filed: Mar. 1, 2018

(51) Int. Cl. H01L 29/808; H01L 29/66; H01L 27/06

(52) U.S. Cl. CPC H01L 29/808; H01L 29/66659; H01L 27/0617; H01L 29/66901

(57) ABSTRACT

An electronic device can include a JFET that overlies a substrate and includes a first well region including a drain region or a source region, or both, and a second well region having the opposite the conductivity type. The second well region can be disposed within the first well region and includes a gate electrode of the JFET. Embodiments as described herein can be used to form a JFET integrated with n-channel and p-channel MISFETs without having to add an additional mask or other process operation to an existing process flow.

### FIELD OF THE DISCLOSURE

The present disclosure relates to electronic devices and processes of forming electronic devices, and more particularly to, electronic devices including a junction field-effect transistor having a gate within a well region and processes of forming the same.

### RELATED ART

Junction field-effect transistors have been integrated into complementary metal-oxide-semiconductor (CMOS) process flows. Consequently, designs of transistors are compromised, process flow can become significantly more complicated, or the like. For example, device structures may have unusual electrical fields that can adversely affect on-state or off-state properties, such as relatively high on-state resistance (R_{DSON}), relatively high off-state leakage current, require usually high gate voltage to properly turn off the transistor, or the like. Alternatively, additional masking or other processing steps may be required. Further improvement of junction field-effect transistors is desired.

### BRIEF DESCRIPTION OF THE DRAWINGS

Embodiments are illustrated by way of example and are not limited in the accompanying figures.

FIG. 1 includes an illustration of a cross-sectional view of a portion of a workpiece including a substrate, a semiconductor layer, and well regions.

FIG. 2 includes an illustration of a cross-sectional view of the workpiece of FIG. 1 after forming other well regions having a conductivity type opposite that of the well regions in FIG. 1.

FIG. 3 includes an illustration of a cross-sectional view of the workpiece of FIG. 2 after forming a gate dielectric layer.

FIG. 4 includes an illustration of a cross-sectional view of the workpiece of FIG. 3 after forming gate electrodes, sidewall spacers, and heavily doped regions.

FIG. 5 includes an illustration of a cross-sectional view of the workpiece of FIG. 4 after forming a substantially completed electronic device.

FIG. 6 includes an illustration of a cross-sectional view of a portion of a workpiece having a channel region of a junction field-effect transistor formed by diffusing dopant under a gate well region.

FIGS. 7 to 9 include illustrations of top views of that can be used for the device as illustrated in FIG. 6.

FIG. 10 includes an illustration of a top view of a portion of a workpiece for a 2×2 junction field-effect transistor matrix after forming well regions and shallow trench isolation.

FIG. 11 includes an illustration of a top view of the workpiece of FIG. 10 after forming heavily doped regions within well regions.

FIG. 12 includes an illustration of a top view of the workpiece of FIG. 11 after forming drain, source, and gate interconnects.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other embodiments can be used based on the teachings as disclosed in this application.

The term “normal operation” and “normal operating state” refer to conditions under which an electronic component or device is designed to operate. The conditions may be obtained from a data sheet or other information regarding voltages, currents, capacitance, resistance, or other electrical conditions. Thus, normal operation does not include operating an electrical component or device well beyond its design limits.

The terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read to include one, at least one, or the singular as also including the plural, or vice versa, unless it is clear that it is meant otherwise. For example, when a single item is described herein, more than one item may be used in place of a single item. Similarly, where more than one item is described herein, a single item may be substituted for that more than one item.

Group numbers corresponding to columns within the Periodic Table of Elements based on the IUPAC Periodic Table of Elements, version dated Nov. 28, 2016.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the semiconductor and electronic arts.

An electronic device can include a junction field-effect transistor (JFET) overlying a substrate and include a first well region having a first conductivity type and a drain region, a source region, or both the drain and source regions, and a second well region having a second conductivity type opposite the first conductivity type. The second well region can be disposed within the first well region and include a gate electrode of the JFET. The second well region can overlie a channel region of the JFET. In an embodiment, a drain contact region can have a dopant concentration sufficient to form an ohmic contact. In another embodiment, the electronic device can also include a metal-insulator-semiconductor field-effect transistor (MISFET) overlying the substrate and including a portion within the first well region, the second well region, or a third well region spaced part from the second well region. The JFET and MISFET can be formed within the same integrated circuit.

Embodiments as described herein can be used to form a JFET without having to add an additional mask or other process operation to a complementary MISFET process flow. The JFET can be formed by leveraging the depth differential between well regions to form a gate electrode over a channel region of the JFET. In the embodiment, an n-well region is deeper than a p-well region, and thus, an n-channel JFET can be formed formed. A semiconductor layer, such an epitaxial layer, of opposite conductivity type to the channel region can be formed to allow the channel region to be pinched off from over and under the channel region. When a p-well region is deeper than an n-well, a p-channel JFET can be formed, and the shallower n-well region can be used to form a gate electrode for the p-channel JFET.

FIG. 1 includes a cross-sectional view of a portion of a workpiece that includes a JFET region 12, an n-channel MISFET region 14, and a p-channel MISFET region 16. The regions 12, 14, and 16 are within the same workpiece and are spaced apart from one another. The workpiece includes a base material 100, a semiconductor layer 120, and one or more well regions 142, 144, and 146. The base material 100 can include a Group 14 element (i.e., carbon, silicon, germanium, or any combination thereof) and can be heavily n-type or p-type doped. For the purposes of this specification, heavily doped is intended to mean a peak dopant concentration of at least approximately 1×10¹⁹ atoms/cm³, and lightly doped is intended to mean a peak dopant concentration of less than approximately 1×10¹⁸ atoms/cm³. The base material 100 can be a portion of a heavily doped wafer (e.g., a heavily n-type doped wafer). In an embodiment, the base material is heavily doped with a n-type dopant, such as arsenic, phosphorus, antimony or the like.

The semiconductor layer 120 is disposed over the base material 100. The semiconductor layer 120 can include one or more Group 14 elements. In an embodiment, the semiconductor layer 120 has a conductivity type opposite the base material 100. In a particular embodiment, the semiconductor layer 120 is a lightly doped p-type epitaxial silicon layer. The dopant can be boron, and the concentration can be in a range of 1×10¹³ atoms/cm³ to 1×10¹⁶ atoms/cm³. The thickness of the semiconductor layer 120 may depend on the designed normal operating voltage of the transistor structures being formed. The thickness of the semiconductor layer 120 can be in a range of approximately 1 micron to approximately 15 microns. The semiconductor layer 120 may be disposed over all of the base material 100.

One or more well regions can be formed within the semiconductor layer 120. Referring to FIG. 1, well regions 142, 144, and 146 are formed within the regions 12, 14, and 16, respectively. The well regions 142, 144, and 146 are formed during the same doping operation. The well regions 142, 144, and 146 can be formed using a single or series of ion implantations, depending on the desired depth of the well regions. The well regions 142, 144, and 146 can be different portions of the same well region, or one or more of the well regions 142, 144, and 146 can be spaced apart from each other or another well region (not illustrated in FIG. 1). The well regions 142, 144, and 146 can have a conductivity type opposite that of the semiconductor layer 120. The well regions 142, 144, and 146 can be lightly doped n-well regions. The dopant can be phosphorus, arsenic, antimony, or the like. The well regions 142, 144, and 146 have an average dopant concentration that is greater than the dopant concentration of the semiconductor layer 120. In an embodiment, the well regions 142, 144, and 146 have an average concentration in a range of 5×10¹³ atoms/cm³ to 1×10¹⁷ atoms/cm³. The depths of the well regions 142, 144, and 146 are shallower than the thickness of the semiconductor layer 120. The depth of the well regions 142, 144, and 146 can be in a range of approximately 0.5 micron to approximately 5 microns.

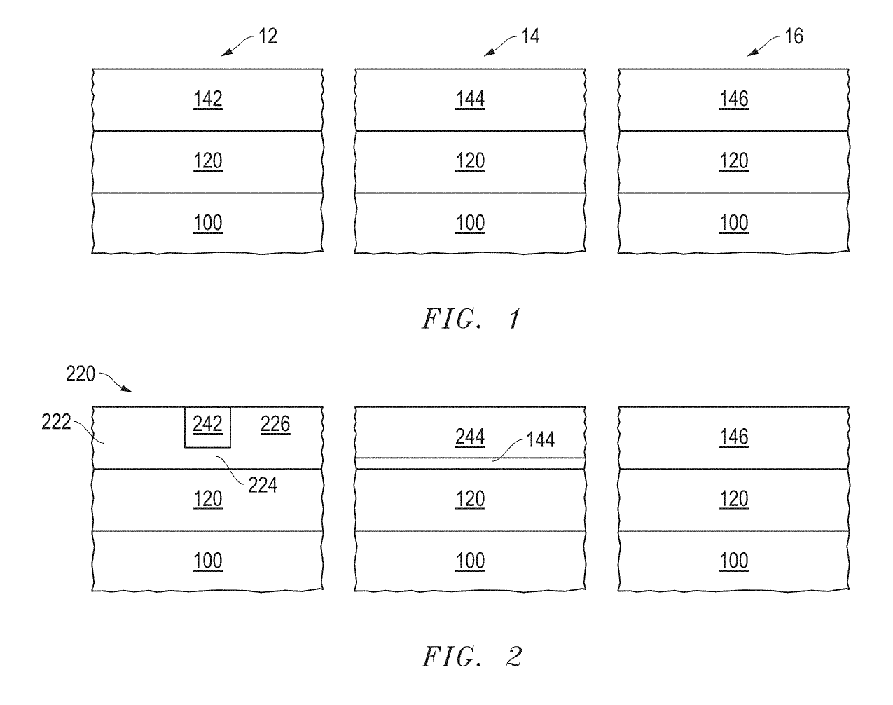

One or more other well regions can be formed within the well regions 142 and 144. Referring to FIG. 2, well regions 242 and 244 are formed within the well regions 142 and 144, respectively. In the embodiment as illustrated, a well region similar to well regions 242 and 244 is not formed within the well regions 146. The regions 242 and 244 can be formed during the same doping operation. The well regions 242 and 244 can be formed using a single or series of ion implantations, depending on the desired depth of the well regions. The well regions 242 and 244 can be different portions of the same well region or one or more of the well regions 242 and 244 can be spaced apart from each other or another well region (not illustrated in FIG. 2). The well regions 242 and 244 can have a conductivity type opposite that of the well regions 142 and 144. The well regions 242 and 244 can be lightly doped p-well regions. The dopant can be boron. The well regions 242 and 244 have an average dopant concentration that is greater than the average dopant concentration of their corresponding well regions 142 and 144. In an embodiment, the well regions have an average dopant concentration in a range of 1×10¹⁴ atoms/cm³ to 5×10¹⁷ atoms/cm³. The depths of the well regions 242 and 244 are shallower than the depths of their corresponding well regions 142 and 144. The depth of the well regions 242 and 244 can be in a range of approximately 0.3 micron to approximately 4.5 microns.

At this point in the process, a JFET 220 is formed within the JFET region 12. The JFET 220 includes a gate electrode that corresponds to the well region 242 within the well region 142. Portions of the well region 142 that are adjacent to the well region 242 include a source region 222, a drain region 226, and a channel region 224 that is disposed between the source region 222 and the drain region 226 and between the well region 242 and the semiconductor layer 120. In the embodiment as illustrated, the JFET 220 is an n-channel JFET. The well region 242, the semiconductor layer 120, or both the well region 242 and the semiconductor layer 120 can be biased to control current flowing through the JFET 220. The thickness of the channel region 224 is the difference in the depths of the well regions 142 and 242. In an embodiment, the thickness of the channel region 224 is at least 0.02 micron, at least 0.11 micron, or at least 0.2 micron, and in another embodiment, the thickness of the channel region 224 is at most 4.0 microns, at most 2.0 microns, or at most 0.9 micron. In addition to the dopant concentration, the other dimensions of the channel region 224 can be selected to achieve a particular on-state resistance and current flow through the channel region 224. After reading this specification, skilled artisans will be able to determine a dopant concentration and dimensions for the channel region 224 to achieve electronic properties as needed or desired for a particular application.

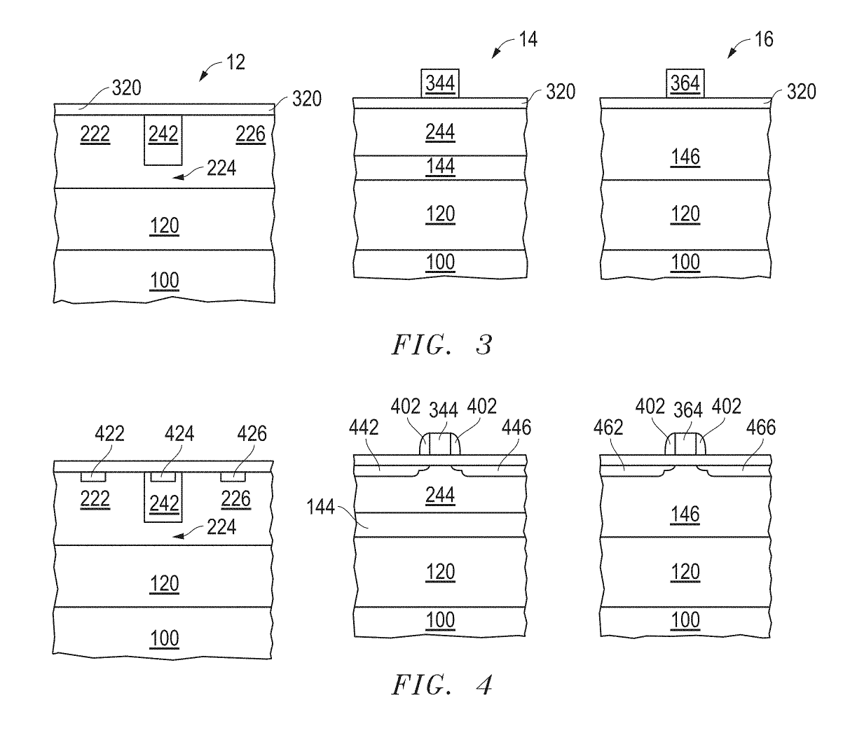

FIG. 3 includes an illustration after forming a gate dielectric layer 320 and gate electrodes 344 and 364. The gate electrode 344 is for the n-channel MISFET being formed in the region 14, and the gate electrode 364 is for the p-channel MISFET being formed in the region 16.

The gate dielectric layer 320 can include one or more films of oxide, nitride, or oxynitride. The gate dielectric layer has a thickness in a range of 2 nm to 15 nm in many applications. The gate dielectric layer can be formed by thermal growth or deposition.

The gate electrodes 344 and 364 are formed by depositing a conductive layer and patterning the conductive layer as illustrated in FIG. 3. The conductive layer can include a semiconductor layer that may be doped in situ or subsequently doped after the layer is deposited. In another embodiment, the conductive layer can include a metal. In still another embodiment, the conductive layer can include a lower film closer to the gate dielectric layer 320 that has a desired work function and an upper film having a different composition that is used for bulk conduction. The conductive layer can have a thickness in a range of 50 nm to 500 nm. Other thicknesses may be used if desired or needed for a particular application. The conductive layer is patterned to define the gate electrodes 344 and 364.

Processing is continued to form the features as illustrated in FIG. 4. Lightly-doped extension regions (also called lightly-doped drain regions) are formed within the well regions 244 and 146. Each of the lightly-doped extension regions have a conductivity type that is opposite that of its corresponding well region. The lightly-doped extension regions formed within the well region 244 can be n-type doped using phosphorus, arsenic, antimony, or the like. The lightly-doped extension regions formed within the well region 146 can be p-type doped using boron. The lightly-doped regions have an average dopant concentration that is greater than the average dopant concentration of their corresponding well regions 244 and 146. In an embodiment, the lightly-doped regions have an average dopant concentration in a range of 5×10¹⁵ atoms/cm³ to 5×10¹⁷ atoms/cm³. The depths of the lightly-doped regions can be in a range of approximately 0.02 micron to approximately 0.9 micron.

A layer is deposited and etched to form sidewall spacers 402. The sacrificial layer can include an oxide, a nitride, an oxynitride and can be conformally deposited over the workpiece, including within regions 12, 14, and 16. The layer can be anisotropically etched to remove the layer from the region 12 and to leave the sidewall spacers 402 adjacent to the gate electrodes 344 and 364.

Heavily doped regions are formed within portions of the source and drain regions 222 and 226 and well regions 244, and 146. In an embodiment, the heavily doped regions have an average dopant concentration of at least 1×10¹⁹ atoms/cm³ to allow ohmic contacts to be made to such regions. The heavily doped regions that are n-type doped can be formed during one doping sequence, and the heavily doped regions that are p-type doped can be formed during another doping sequence. The depths of the heavily-doped regions can be in a range of approximately 0.02 micron to approximately 0.9 micron.

Within region 12, source contact region 422, gate contact region 424, and drain contact region 426 are formed. In an embodiment, the source and drain contact regions 422 and 426 is n-type doped, and the gate contact region 424 is p-type doped. Within the region 14, a source region 442 and a drain region 446 include a combination of the lightly-doped extension region and a heavily-doped region. In an embodiment, the source and drain regions 442 and 446 are n-type doped. The source and drain contact regions 422 and 426 and the heavily-doped portions of the source and drain regions 442 and 446 can be formed using the same doping sequence. Within the region 16, a source region 462 and a drain region 466 include a combination of the lightly-doped extension region and a heavily-doped region. In an embodiment, the source and drain regions 462 and 466 are p-type doped. The gate contact region 424 and the heavily-doped portions of the source and drain regions 462 and 466 can be formed using the same doping sequence. The heavily-doped portions of the source and drain regions 442, 446, 462, and 466 are source and drain contact regions for the MISFETs in regions 14 and 16.

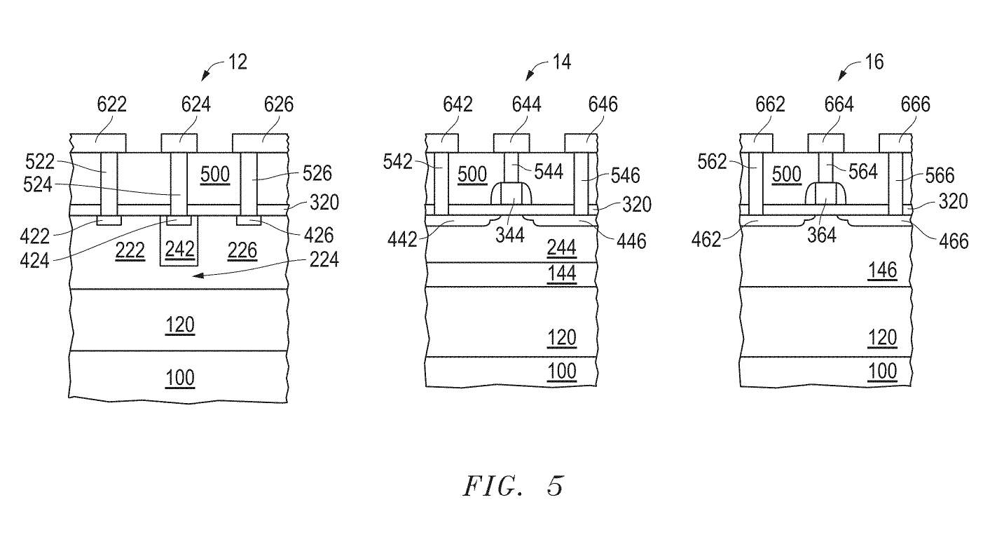

FIG. 5 includes an illustration of the workpiece after forming an interlevel dielectric (ILD) layer 500 over the gate dielectric layer 320, the gate electrodes 344 and 364, and the sidewall spacers 402. The ILD layer 500 can include an oxide, a nitride, an oxynitride, or any combination thereof. The ILD layer 500 can include a single film having a substantially constant or changing composition (e.g., a high phosphorus content further from the semiconductor layer 120) or a plurality of discrete films. An etch-stop film, an antireflective film, or a combination may be used within or over the ILD layer 500 to help with processing. The ILD layer 500 can be deposited to a thickness in a range of approximately 0.5 micron to approximately 2.0 microns. Portions of the ILD layer 500 and the gate dielectric layer 320 are patterned to define contact openings.

A conductive layer can be formed within the contact openings and over the ILD layer 500 and etched to form conductive plugs 522, 524, 526, 542, 544, 546, 562, 564, and 566, as illustrated in FIG. 5. The conductive plug 522 is electrically connected to the source contact region 422, the conductive plug 524 is electrically connected to the gate contact region 424, and the conductive plug 526 is electrically connected to the drain contact region 426. The conductive plug 542 is electrically connected to the source region 442, the conductive plug 544 is electrically connected to the gate electrode 344, and the conductive plug 546 is electrically connected to the drain region 446. The conductive plug 562 is electrically connected to the source region 462, the conductive plug 564 is electrically connected to the gate electrode 364, and the conductive plug 566 is electrically connected to the drain region 466.

In an embodiment, the conductive plugs 522, 524, 526, 542, 544, 546, 562, 564, and 566 can be formed from a conductive layer having a plurality of films. In an embodiment, a layer including a refractory metal, such as Ti, Ta, W, Co, Pt, or the like, can be deposited over the workpiece and within the contact openings. The workpiece can be annealed so that portions of the film including the refractory metal are selectively reacted with exposed silicon at the bottom of the contact openings, such as substantially monocrystalline or polycrystalline silicon, to form a metal silicide. A metal nitride film may be formed to further fill a part, but not the remainder, of the openings. The metal nitride film can act as a barrier film. A conductive material fills the remainder of the contact openings, the conductive fill material can include W. Portions of the layer including the refractory metal, the metal nitride film, and the conductive film material that overlie the ILD layer 500 are removed to form the conductive plugs 522, 524, 526, 542, 544, 546, 562, 564, and 566.

As illustrated in the embodiment of FIG. 5, interconnects 622, 624, 626, 642, 644, 646, 662, 664, and 666 overlie and are electrically connected to the conductive plugs 522, 524, 526, 542, 544, 546, 562, 564, and 566, respectively. The interconnects 622, 624, 626, 642, 644, 646, 662, 664, and 666 are formed from a conductive layer that can include one or more films. In an embodiment, the interconnects 622, 624, 626, 642, 644, 646, 662, 664, and 666 can include a bulk conductive film that includes mostly Al or Cu. When the conductive layer includes a plurality of films, an adhesion film or a barrier film can be deposited before the bulk conductive film. An antireflective film can be formed over the bulk conductive film and can include a metal nitride film. The conductive layer can have a thickness in a range of 0.5 micron to 3 microns. The conductive layer can be patterned to form the interconnects 622, 624, 626, 642, 644, 646, 662, 664, and 666.

One or more other interconnect levels and a passivation layer may be formed over the workpiece. Each interconnect level can include an interlevel dielectric layer and interconnects. A conductive layer can be used at each interconnect level. The conductive layer may be the same or different from the other conductive layers described with respect to the interconnects 622, 624, 626, 642, 644, 646, 662, 664, and 666. The passivation layer can be formed over the uppermost interconnect level and patterned to expose bond pads.

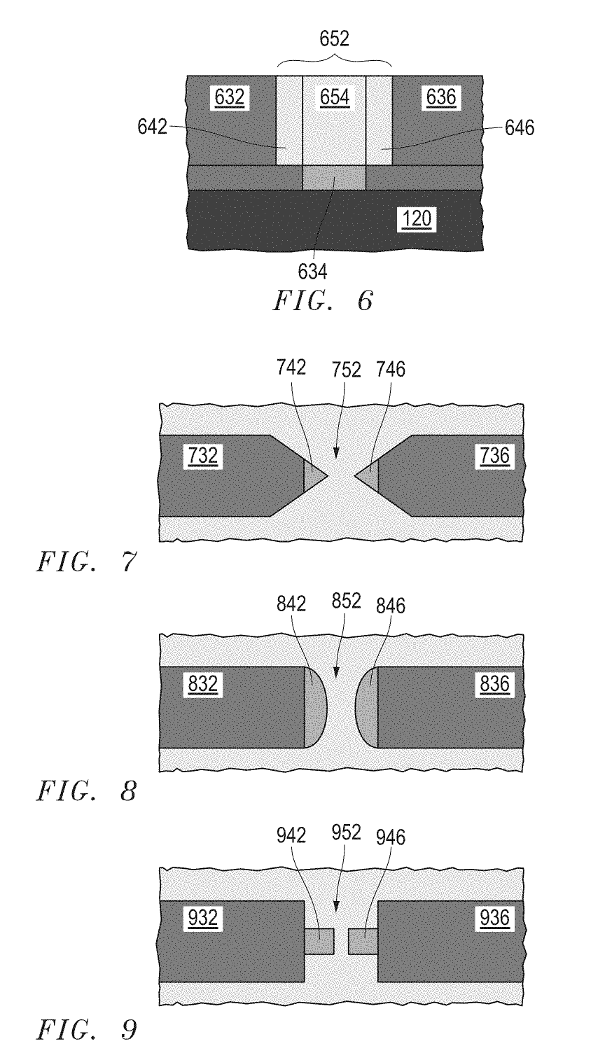

In a further embodiment, a portion of a channel region of the JFET can be formed by diffusion, and a portion of a gate can be formed such that it does not include a counter doped portion of a well region. FIG. 6 includes a cross-sectional view of a workpiece after forming the well regions. Well regions 632 and 636 are similar to the well region 142 except that within the JFET region 12, the well region 632 and 636 are formed only within a portion of the region. In particular embodiment, another well region 652 is similar to the well region 242. The well region 652 between the well regions 632 and 636 is a gate electrode for the JFET as illustrated in FIG. 6. Counter doped regions 642 and 646 have the same conductivity type as the well region 652 because the well region 652 has a higher dopant concentration than the well regions 632 and 636. The portion 654 of the well region 652 is not counterdoped by the well regions 632 and 636.

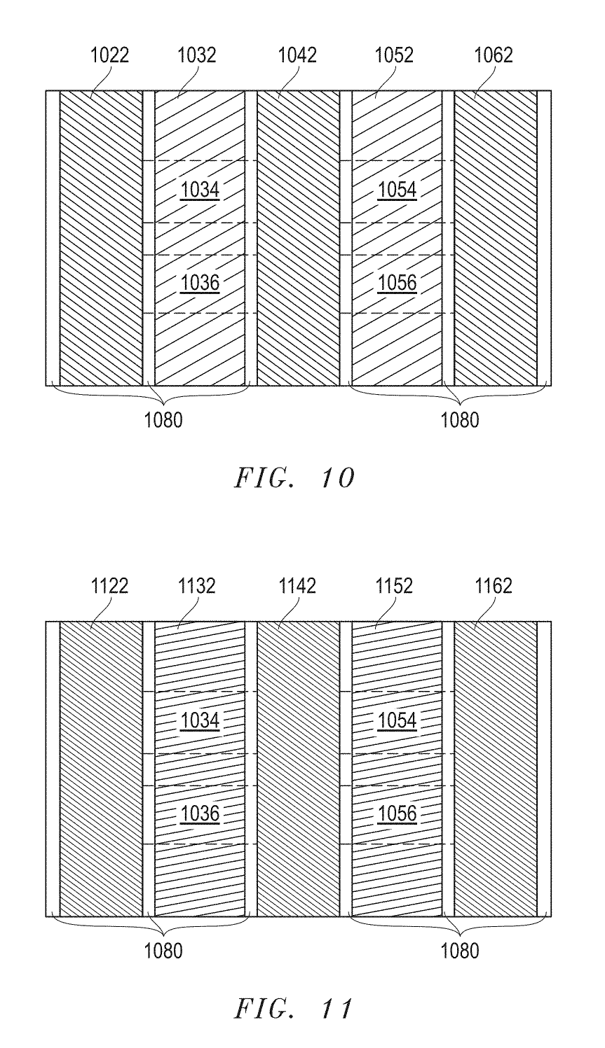

Unlike the prior embodiment in which all of the well region 242 is illustrated as counter doping a portion the well region 142, in this embodiment, a portion, and not all of the JFET region is doped when forming the source and drain regions. In FIGS. 7, 8, and 9, source regions 732, 832, and 932, counter doped regions 742, 746, 842, 846, 942, and 946 and drain regions 736, 836, and 936 are doped during the same doping sequence; however, all other portions illustrated in FIGS. 7, 8, and 9 are not doped during such doping sequence. Another dopant of the opposite conductivity is implanted to form the well regions 752, 852, and 952. In FIGS. 7, 8, and 9, all of the JFET regions are doped except for the source and drain regions 732, 832, 932, 736, 836, and 936. The counter doped regions 742, 746, 842, 846, 942, and 946 have the same conductivity type as the well regions 752, 852, and 952. The counter doped regions 742, 746, 842, 846, 942, and 946 and portions of well regions 752, 852, and 952 between the corresponding source and drain regions are gate electrodes. After reading this specification, skilled artisans will appreciate that other layouts can be used without deviating from the concepts described herein.

In a further embodiment, more than one JFET can be formed in a side-by-side layout. FIGS. 10 to 12 include top views of a layout that can be used to form a 2×2 matrix of JFETs. Referring to FIG. 10, well regions 1022, 1034, 1036, 1042, 1054, 1056, and 1062 can be formed during the same doping sequence. In a particular embodiment, all of the well regions are parts of a single well region. The well regions 1034, 1036, 1054, and 1054 are channel regions for the JFETs that underlie well regions 1032 and 1052, and thus are illustrated with dashed lines. The dopant concentrations and depths of the well regions 1022, 1034, 1036, 1042, 1054, 1056, and 1062 can be any of the dopant concentrations and depths as previously described with respect to the well region 142. Well regions 1032 and 1052 can be formed during the same doping sequence but different from the doping sequence used to form well regions 1022, 1034, 1036, 1042, 1054, 1056, and 1062. The dopant concentrations and depths of the well regions 1032 and 1052 can be any of the dopant concentrations and depths as previously described with respect to the well region 242. In a particular embodiment, well regions 1022, 1034, 1036, 1042, 1054, 1056, and 1062 are n-type doped, and well regions 1032 and 1052 are p-type doped. Although not illustrated in FIG. 10, the well regions in FIG. 10 can be formed in a semiconductor layer having the same conductivity type as the well regions 1032 and 1052. In this embodiment, the channel regions that corresponding to the well regions 1034, 1036, 1054, and 1056 underlying the well regions 1032 and 1052 may be pinched off from the side when the semiconductor layer and well regions 1032 and 1052 are appropriately biased. A shallow trench isolation 1080 is formed at the locations as depicted in FIG. 10. The depth of the shallow trench isolation 1080 is less than the depth of the well regions.

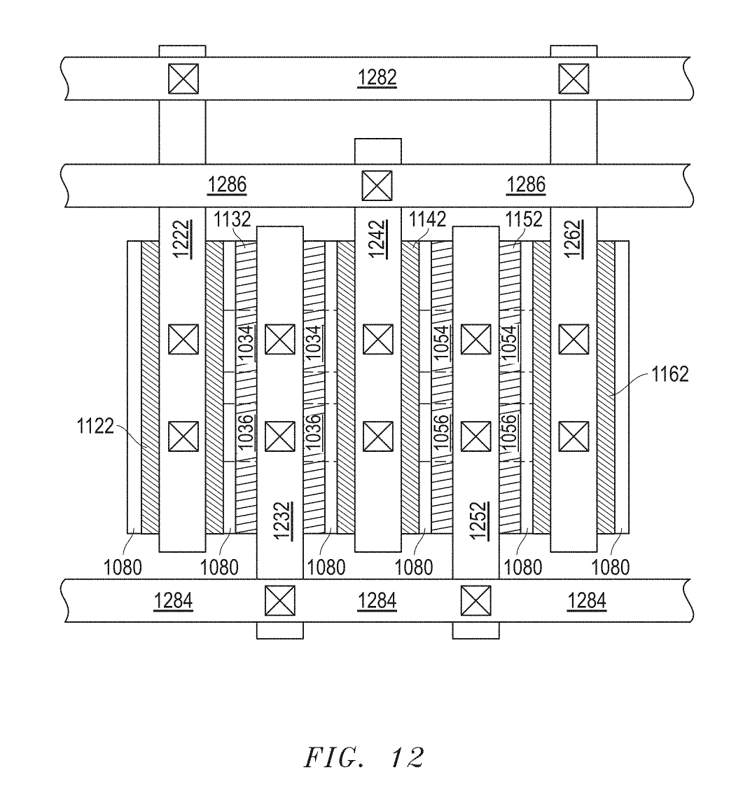

Referring to FIG. 11, heavily-doped regions are formed within the well regions to allow ohmic contacts to be formed during subsequent processing. Heavily-doped regions 1122, 1142, and, 1162 can be formed during the same doping sequence. The dopant concentrations and depths of the heavily-doped regions 1122, 1142, and, 1162 can be any of the dopant concentrations and depths as previously described with respect to the heavily-doped regions 422 and 426. Heavily-doped regions 1132 and 1152 can be formed during the same doping sequence but different from the doping sequence used to form heavily-doped regions 1122, 1142, and, 1162. The dopant concentrations and depths of the heavily-doped regions 1132 and 1152 can be any of the dopant concentrations and depths as previously described with respect to the heavily-doped region 424. In a particular embodiment, heavily-doped regions 1122, 1132, 1142, and, 1162 are n-type doped, and heavily-doped regions 1132 and, 1152 are p-type doped.

FIG. 12 includes a top view of the JFETs after forming interconnects. The interconnect 1222 is electrically connected to the well regions 1022 and to a source interconnect 1282. The interconnect 1232 is electrically connected to well regions 1032 and to a gate interconnect 1284. The interconnect 1242 is electrically connected to the well regions 1042 and to a drain interconnect 1286. The interconnect 1252 is electrically connected to the well regions 1052 and to the gate interconnect 1284. The interconnect 1262 is electrically connected to the well regions 1062 and to the source interconnect 1282. Contact between an interconnect and an underlying well region or interconnect is designated with an “X” within a box.

The embodiment as illustrated in FIGS. 10 to 12 illustrates two JFETs along each row and each column. Different organizations of JFETs are possible. Another organization can have more or fewer rows or more or fewer columns. Furthermore, the orientation of the gate interconnect 1284 and either or both of the source and drain interconnects 1282 and 1286 can be orthogonal to each other to allow less than all of the JFETs within the matrix to be turned on and off as compared to other JFETs within the matrix. After reading this specification, skilled artisans will able to design a matrix of JFETs to meet the needs or desires for a particular application.

Embodiments as described herein can be used to form a JFET without having to add an additional mask or other process operation to a complementary MISFET process flow. The JFET can be formed by leveraging the depth differential between well regions. In the embodiment as illustrated, the n-well region 142 is deeper than the p-well region 242, and thus, an n-channel JFET is formed. When a p-well region is deeper than an n-well, a p-channel JFET can be formed, and the shallower n-well region can be used to form a gate for the p-channel JFET. The semiconductor layer 120 may be replaced to selectively dope with an n-type dopant to allow the channel region of the p-channel JFET to be pinched off from both sides. Thus, a separate depletion implant and its corresponding mask are not needed to form a depletion-mode transistor. The JFET can be an n-channel depletion-mode transistor and, thus, can have lower on-state resistance as compared to a comparably sized p-channel transistor.

Many different aspects and embodiments are possible. Some of those aspects and embodiments are described below. After reading this specification, skilled artisans will appreciate that those aspects and embodiments are only illustrative and do not limit the scope of the present invention. Embodiments may be in accordance with any one or more of the items as listed below.

### Embodiment 1

An electronic device can include: a first junction field-effect transistor overlying a substrate and including: a first well region having a first conductivity type and including a drain region, a source region, or both the drain and source regions; a second well region having a second conductivity type opposite the first conductivity type, wherein: the second well region is disposed within the first well region and includes a first gate electrode of the first junction field-effect transistor, and the second well region overlies a channel region of the first junction field-effect transistor; and a first metal-insulator-semiconductor field-effect transistor overlying the substrate and including a portion within the first well region, the second well region, or a third well region spaced part from the second well region.

### Embodiment 2

The electronic device of Embodiment 1, wherein the portion of the first metal-insulator-semiconductor field-effect transistor includes a channel region within the third well region.

### Embodiment 3

The electronic device of Embodiment 2, wherein the third well region has the second conductivity type.

### Embodiment 4

The electronic device of Embodiment 2, wherein the channel region of the first junction field-effect transistor has a dopant concentration that is substantially constant, as measured along a line substantially parallel to a bottom of the second well region.

### Embodiment 5

The electronic device of Embodiment 2, wherein the channel region of the first junction field-effect transistor has a dopant concentration that is the lowest at midpoint between the drain and source regions, as measured along a line substantially parallel to a bottom of the second well region.

### Embodiment 6

The electronic device of Embodiment 1, wherein the substrate includes a base material and a doped layer, wherein the channel region of the first junction field-effect transistor is disposed between the doped layer and the second well region.

### Embodiment 7

The electronic device of Embodiment 6, wherein the channel region of the first junction field-effect transistor has the first conductivity type, and the doped layer has the second conductivity type.

### Embodiment 8

The electronic device of Embodiment 1, further including a second metal-insulator-semiconductor field-effect transistor including a portion within a fourth well region having the first conductivity type, wherein one of the first and second metal-insulator-semiconductor field-effect transistors is an n-channel transistor, and the other of the first and second metal-insulator-semiconductor field-effect transistors is a p-channel transistor.

### Embodiment 9

The electronic device of Embodiment 1, wherein the first well region is an n-well region, and the second well region is a p-well region.

### Embodiment 10

The electronic device of Embodiment 1, further including drain contact regions having a dopant concentration of at least 1×10¹⁹ atoms/cm³.

### Embodiment 11

The electronic device of Embodiment 10, further including source contact regions having a dopant concentration of at least 1×10¹⁹ atoms/cm³.

### Embodiment 12

The electronic device of Embodiment 11, further including interconnects that make ohmic contact to the source and drain contact regions.

### Embodiment 13

The electronic device of Embodiment 1, wherein the first junction and first metal-insulator-semiconductor field-effect transistors are within a same integrated circuit.

### Embodiment 14

The electronic device of Embodiment 1, wherein the third well region is within the first well region and includes a second gate electrode of a second junction field-effect transistor, and the third well region overlies a channel region of the second junction field-effect transistor.

### Embodiment 15

The electronic device of Embodiment 1, further including a second metal-insulator-semiconductor field-effect transistor, drain contact regions, source contact regions, and interconnects, wherein: the first metal-insulator-semiconductor field-effect transistor includes a second gate electrode, the second metal-insulator-semiconductor field-effect transistor includes a third gate electrode and a portion within the first well region, each of the drain and source contact regions of the first junction field-effect and first and second metal-insulator-semiconductor field-effect transistors have a dopant concentration of at least 1×10¹⁹ atoms/cm³, the interconnects make ohmic connections to the drain and source contact regions and the first, second, and third gate electrodes, and the first junction and the first metal-insulator-semiconductor field-effect transistors are n-channel transistors, and the second metal-insulator-semiconductor field-effect transistor is a p-channel transistor.

### Embodiment 16

An electronic device including a junction field-effect transistor including: a first well region having a first conductivity type and including a drain region and a source region; a second well region having a second conductivity type opposite the first conductivity type, wherein: the second well region is disposed within the first well region and includes a gate electrode, and the second well region overlies a channel region of the junction field-effect transistor; a drain contact region having a dopant concentration sufficient to form an ohmic contact.

### Embodiment 17

The electronic device of Embodiment 16, further including a source contact region having a dopant concentration sufficient to form an ohmic contact.

### Embodiment 18

A process of forming an electronic device including: forming a first well region within a substrate, wherein the first well region has a first conductivity type; forming a second well region and a third well region within the first well region, wherein: each of the second and third well regions has a second conductivity type opposite the first conductivity type, the second well region is spaced apart from the third well region, and the second well region includes a first gate electrode of a junction field-effect transistor; forming a gate dielectric layer over substrate; and forming a second gate electrode of a first metal-insulator-semiconductor field-effect transistor, wherein the gate dielectric layer is disposed between the third well region and the second gate electrode; wherein in a finished device, the junction field-effect transistor includes a portion of the first well region and the first gate electrode; and the first metal-insulator-semiconductor field-effect transistor includes a portion of the third well region, the gate dielectric layer, and the second gate electrode.

### Embodiment 19

The process of Embodiment 18, further including forming source contact regions for the junction and first metal-insulator-semiconductor field-effect transistors; forming drain contact regions for the junction and first metal-insulator-semiconductor field-effect transistors; and forming ohmic contacts to the source and drain contact regions.

### Embodiment 20

The process of Embodiment 18, wherein: forming the first well region further includes forming a fourth well region having the first conductivity type, forming the second gate electrode further includes forming a third gate electrode, wherein the gate dielectric layer is disposed between the fourth well region and the third gate electrode, wherein in a finished device, a second metal-insulator-semiconductor field-effect transistor includes a portion of the fourth well region, the gate dielectric layer, and the third gate electrode, and wherein one of the first and second metal-insulator-semiconductor field-effect transistors is an n-channel transistor, and the other of the first and second metal-insulator-semiconductor field-effect transistors is a p-channel transistor.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

1. An electronic device comprising:
a first junction field-effect transistor overlying a substrate and including:
a first well region having a first conductivity type and including a drain region, a source region, or both the drain and source regions;
a second well region having a second conductivity type opposite the first conductivity type, wherein:
the second well region is disposed within the first well region and includes a first gate electrode of the first junction field-effect transistor, and
the second well region overlies a channel region of the first junction field-effect transistor; and
a first metal-insulator-semiconductor field-effect transistor overlying the substrate and including a portion within the first well region, the second well region, or a third well region spaced part from the second well region.

2. The electronic device of claim 1, wherein the portion of the first metal-insulator-semiconductor field-effect transistor includes a channel region within the third well region, wherein the third well region has the second conductivity type.

3. The electronic device of claim 1, further comprising forming a gate contact region within the second well region, wherein the second well region is a lightly doped region.

4. The electronic device of claim 2, wherein the channel region of the first junction field-effect transistor has a dopant concentration that is substantially constant, as measured along a line substantially parallel to a bottom of the second well region.

5. The electronic device of claim 2, wherein the channel region of the first junction field-effect transistor has a dopant concentration that is the lowest at midpoint between the drain and source regions, as measured along a line substantially parallel to a bottom of the second well region.

6. The electronic device of claim 1, wherein the substrate includes a base material and a doped layer, wherein the channel region of the first junction field-effect transistor is disposed between the doped layer and the second well region.

7. The electronic device of claim 6, wherein the channel region of the first junction field-effect transistor has the first conductivity type, and the doped layer has the second conductivity type.

8. The electronic device of claim 1, further comprising a second metal-insulator-semiconductor field-effect transistor including a portion within a fourth well region having the first conductivity type, wherein one of the first and second metal-insulator-semiconductor field-effect transistors is an n-channel transistor, and the other of the first and second metal-insulator-semiconductor field-effect transistors is a p-channel transistor.

9. The electronic device of claim 1, wherein the first well region is an n-well region, and the second well region is a p-well region.

10. The electronic device of claim 1, further comprising drain contact regions having a dopant concentration of at least 1×10¹⁹ atoms/cm³.

11. The electronic device of claim 10, further comprising source contact regions having a dopant concentration of at least 1×10¹⁹ atoms/cm³.

12. The electronic device of claim 11, further comprising interconnects that make ohmic contact to the source and drain contact regions.

13. The electronic device of claim 1, wherein the first junction and first metal-insulator-semiconductor field-effect transistors are within a same integrated circuit.

14. The electronic device of claim 1, wherein:
the third well region is within the first well region and includes a second gate electrode of a second junction field-effect transistor, and
the third well region overlies a channel region of the second junction field-effect transistor.

15. The electronic device of claim 1, further comprising a second metal-insulator-semiconductor field-effect transistor, drain contact regions, source contact regions, and interconnects, wherein:
the first metal-insulator-semiconductor field-effect transistor includes a second gate electrode,
the second metal-insulator-semiconductor field-effect transistor includes a third gate electrode and a portion within the first well region,
each of the drain and source contact regions of the first junction field-effect and first and second metal-insulator-semiconductor field-effect transistors have a dopant concentration of at least 1×10¹⁹ atoms/cm³,
the interconnects make ohmic connections to the drain and source contact regions and the first, second, and third gate electrodes, and
the first junction and the first metal-insulator-semiconductor field-effect transistors are n-channel transistors, and the second metal-insulator-semiconductor field-effect transistor is a p-channel transistor.

16. An electronic device comprising:
a junction field-effect transistor including:
a first well region having a first conductivity type and including a drain region and a source region;
a second well region having a second conductivity type opposite the first conductivity type, wherein:
the second well region is disposed within the first well region and includes a gate electrode, and
the second well region overlies a channel region of the junction field-effect transistor;
a drain contact region having a dopant concentration sufficient to form an ohmic contact.

17. The electronic device of claim 16, further comprising a gate contact region with the second well region, and a source contact region having a dopant concentration sufficient to form an ohmic contact.

18. A process of forming an electronic device comprising:
forming a first well region within a substrate, wherein the first well region has a first conductivity type;
forming a second well region and a third well region within the first well region, wherein:
each of the second and third well regions has a second conductivity type opposite the first conductivity type,
the second well region is spaced apart from the third well region, and
the second well region includes a first gate electrode of a junction field-effect transistor;
forming a gate dielectric layer over substrate; and
forming a second gate electrode of a first metal-insulator-semiconductor field-effect transistor, wherein the gate dielectric layer is disposed between the third well region and the second gate electrode;
wherein in a finished device, the junction field-effect transistor includes a portion of the first well region and the first gate electrode; and the first metal-insulator-semiconductor field-effect transistor includes a portion of the third well region, the gate dielectric layer, and the second gate electrode.

19. The process of claim 18, further comprising:
forming a gate contact region with the second well region, wherein the second well region is a lightly doped region;
forming source contact regions for the junction and first metal-insulator-semiconductor field-effect transistors;
forming drain contact regions for the junction and first metal-insulator-semiconductor field-effect transistors; and
forming ohmic contacts to the source and drain contact regions.

20. The process of claim 18, wherein:
forming the first well region further comprises forming a fourth well region having the first conductivity type,
forming the second gate electrode further comprises forming a third gate electrode, wherein the gate dielectric layer is disposed between the fourth well region and the third gate electrode,
wherein in a finished device, a second metal-insulator-semiconductor field-effect transistor includes a portion of the fourth well region, the gate dielectric layer, and the third gate electrode, and
wherein one of the first and second metal-insulator-semiconductor field-effect transistors is an n-channel transistor, and the other of the first and second metal-insulator-semiconductor field-effect transistors is a p-channel transistor.
